(19) United States
(12) Patent Application Publication
(10) Pub. No.: US 2008/0164894 A1
(43) Pub. Date: Jul. 10, 2008

(54) System and method for testing semiconductor integrated circuit in parallel

(75) Inventors: Min-Gu Kim, Yongin-si (KR); Young-Soo An, Yongin-si (KR); Ho-Jeong Choi, Yongin-si (KR); Jung-Hyeon Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/006,560

(22) Filed: Jan. 3, 2008

(30) Foreign Application Priority Data
Jan. 4, 2007 (KR) 10-2007-0001183

(51) Int. Cl. G01R 31/26

(52) U.S. Cl. 324/754; 324/765

(57) ABSTRACT

A system and method for testing a semiconductor integrated circuit (IC) in parallel includes a probe chuck, a test head, and a test controller. The probe chuck loads a plurality of different types of semiconductor DUTs. The test head provides a plurality of circuit sites to independently and simultaneously test the different types of semiconductor DUTs, and the test controller controls the test head and the probe chuck.

### CROSS-REFERENCE TO RELATED PATENT APPLICATION

This application claims the benefit of Korean Patent Application No. 10-2007-0001183, filed on Jan. 4, 2007, in the Korean Intellectual Property Office, the contents of which are incorporated herein in their entirety by reference.

### BACKGROUND OF THE INVENTION

1. Field of the Invention

The present invention relates to a system and method for testing a semiconductor integrated circuit (IC) and, more particularly, to a system and method for testing a semiconductor integrated circuit (IC) in parallel.

2. Description of the Related Art

In general, a semiconductor device formed on a semiconductor substrate made of silicon, for example, is manufactured using a sequence of unit processes including a process of stacking layers, a process of doping an impurity, and photolithography and etching processes for patterning the layers. In order to determine whether each of the individual steps is properly performed to manufacture a semiconductor device having target design parameters, devices such as transistors, capacitors, resistors, and inductors, are inspected for defects or to evaluate the parameter characteristics after performing each of the unit processes.

In order to evaluate the characteristics of such devices, a semiconductor IC testing system for testing a semiconductor integrated circuit (IC) may be used. The semiconductor IC testing system applies electric signals to each of a plurality of semiconductor devices formed on a wafer and senses electric signals generated from the semiconductor devices. The semiconductor IC testing system can be a single type semiconductor IC testing system for probing a single test module at a time or a parallel type semiconductor IC testing system for testing a plurality of test modules in test module groups arranged at different locations on a wafer, simultaneously.

FIG. 1 is a diagram illustrating a testing method using a conventional parallel type semiconductor IC testing system.

Referring to FIG. 1, for example, an operator may select one of a transistor, a capacitor, an inductor, and a resistor as a test item. The operator then determines N test locations on a wafer in which the selected test item is to be tested. As illustrated in FIG. 1, four test locations 10 on a wafer may be determined when a transistor is selected as the test item. When a resistor is selected as the test item, about half of the resistors arranged on a wafer may be determined as test locations 20.

In a conventional parallel type semiconductor IC testing system as illustrated in FIG. 1, one type of test item can be tested at a plurality of test locations in parallel. However, different types of test items must be tested in a time-serial manner. For example, tests S10 for testing transistors may be simultaneously performed at four test locations 10 of a wafer W. After finishing the tests S10, other tests S20 for testing resistors can be performed at test locations 20 corresponding to about half of the resistors on the wafer W.

The transistor tests S10 are performed by a transistor test program P10 loaded on the parallel type semiconductor IC, testing system, and the resistor tests S20 are performed by a resistor test program P20. In each of the tests S10 and S20, the tests can be performed in different test locations, at the same time.

As described above, in a conventional parallel type semiconductor IC testing system as illustrated in FIG. 1, one type of test item can be tested in parallel. However, in a conventional parallel type semiconductor IC testing system, different types of test items must be tested in a time-serial manner. When testing different types of test items, a conventional parallel type semiconductor IC testing system has low throughput similar to that of a single type semiconductor IC testing system. Since different types of test items require the use of different system resources, some of the system resources are not used while testing one type of test item. Therefore, the resources of such an expensive system are idled and wasted.

### SUMMARY OF THE INVENTION

The present invention provides a semiconductor IC testing system having an increased test speed and a high test throughput by testing a plurality of different types of semiconductor DUTs (device under test) in parallel.

The present invention also provides a semiconductor IC testing system that optimally uses its resources by testing semiconductor DUTs using all the resources of the system.

The present invention also provides a semiconductor IC test method for providing an increased test speed and a high test throughput by testing a plurality of different types of semiconductor DUTs in parallel.

The present invention also provides a semiconductor IC test method that optimally uses resources of an expensive testing system by testing semiconductor DUTs using all the resources of the system.

According to an aspect of the present invention, there is provided a system for testing semiconductor devices in parallel. The system includes a probe chuck for loading a plurality of different types of semiconductor DUTs. A test head provides a plurality of circuit sites to independently and simultaneously test the different types of semiconductor DUTs. A test controller controls the test head and the probe chuck.

The test head may include a probe card having a needle unit arranged to contact contact pads of the semiconductor DUTs; a pin board mounted on the probe card for inputting and outputting signals to the needle unit selected by a relay of a switching metric circuit; and a plurality of source monitor units connected to the pin board for generating and detecting the signals.

Each of the circuit sites may include a microprocessor.

Different types of test programs may be allocated to the circuit sites and may run independently. Different resources may be provided to each of the circuit sites. The controller may provide an operator interface for creating a test map.

The semiconductor DUTs may be one or more of a transistor, a capacitor and a resistor. The semiconductor DUTs may be formed on a scribe line disposed between dies on a wafer.

Since different types of test programs may be allocated to the circuit sites and run independently, the system according to the present embodiment can test different test items in parallel. Therefore, testing time is shortened, and throughput is increased.

According to another aspect of the present invention, there is provided a system for testing semiconductor devices in parallel. The system includes a probe chuck that can be loaded with different types of semiconductor DUTs. A test head provides two or more circuit sites that can be used as a single circuit site by combining allocated resources. A test controller controls the test head and the probe chuck.

The test head may include: a probe card having a needle unit arranged to contact contact pads of the semiconductor DUTs; a pin board mounted on the probe card for inputting and outputting signals to the needle unit selected by a relay of a switching metric circuit; and a plurality of source monitor units connected to the pin board for generating and detecting the signals.

Each of the circuit sites may include a microprocessor. Different types of test programs may be allocated to the circuit sites and may run independently. The test controller may provide an operator interface for creating a test map. Semiconductor DUTs may include a flash memory device. The semiconductor DUTs may be formed on a scribe line disposed between dies on a wafer.

The system according to the present embodiment includes at least two circuit sites that can be used as single circuit site by combining allocated resources. Since the semiconductor devices are tested using redundant test resources, the resources of such expensive test system are optimally utilized not to remain idle.

According to still another aspect of the present invention, there is provided a method of testing semiconductor devices in parallel. The method includes: providing a plurality of different types of semiconductor DUTs; selecting at least two different types of test items; selecting the different types of semiconductor DUTs arranged at different locations in order to test the test items; and testing the different types of semiconductor DUTs independently and simultaneously.

The semiconductor DUTs may be test devices formed at a scribe line arranged between dies of a semiconductor substrate.

In the testing of the different types of semiconductor DUTs, test resources allocated to the different types of semiconductor DUTs may be independently used. The method further include combining test resources allocated to the semiconductor DUTs, allocating and using the combined test resources for a large semiconductor DUT when the different types of semiconductor DUTs comprise the large semiconductor DUT requiring expanded test resources.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic diagram illustrating a testing method using a conventional parallel type semiconductor test system.

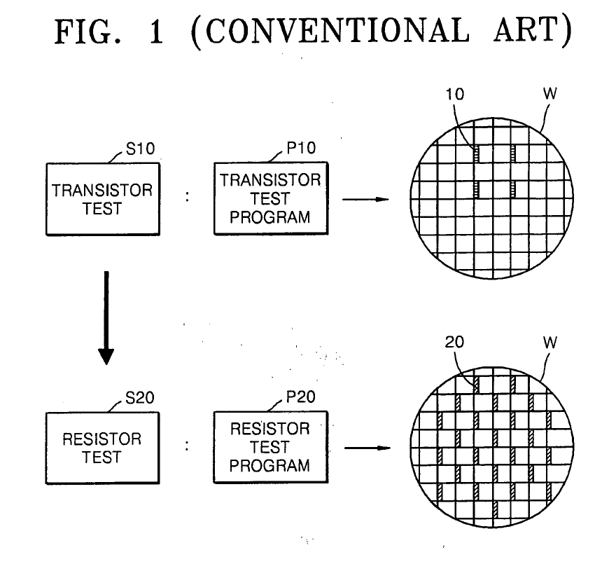

FIG. 2 is a schematic block diagram illustrating a semiconductor IC testing system according to an embodiment of the present invention.

FIG. 3 is a schematic block diagram illustrating circuit sites of a semiconductor IC testing system according to an embodiment of the present invention.

FIG. 4 is a schematic diagram illustrating a test map for an exemplary test mode performed by the semiconductor IC testing system illustrated in FIG. 3, according to an embodiment of the present invention.

FIG. 5 is a schematic block diagram illustrating circuit sites of a semiconductor IC testing system according to another embodiment of the present invention.

FIG. 6 is a schematic diagram illustrating a test map for an exemplary test mode realized by the semiconductor IC testing system illustrated in FIG. 5, according to an embodiment of the present invention.

### DETAILED DESCRIPTION OF PREFERRED EMBODIMENTS OF THE INVENTION

The present invention will now be described more fully with reference to the accompanying drawings, in which exemplary embodiments of the invention are shown.

In the specification, although terms “a first” and “a second” may be used to describe various members, parts, regions, and/or portions, it is obvious to those skilled in the art that members, parts, regions, and/or portions are not limited by the terms. The terms are used only to identify one member, part, region, or portion. Therefore, a first member, part, region, or portion may designate a second member, part, region, or portion.

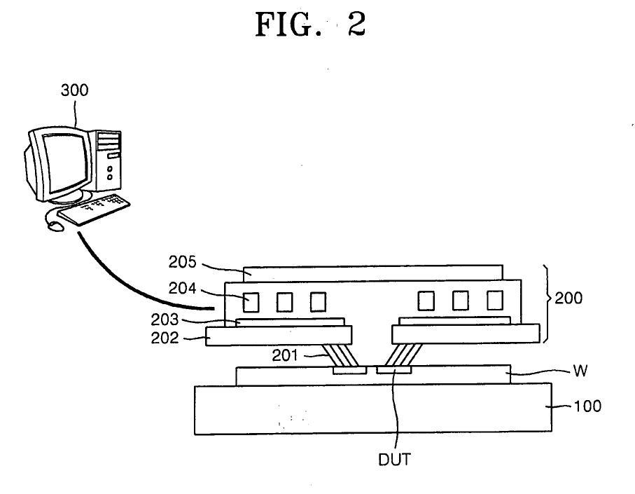

FIG. 2 is a block diagram illustrating a semiconductor IC testing system for testing semiconductor integrated (IC) chips, according to an embodiment of the present invention.

Referring to FIG. 2, the parallel type semiconductor IC testing system for parallel testing semiconductor ICs according to the present embodiment includes a probe chuck 100 for loading a wafer W, a test head 200 for testing a plurality of semiconductor DUTs (device under test) arranged on the wafer W, and a test controller 300 for controlling the probe chuck 100 and the test head 200. As is well-known to those of ordinary skill in the art, the probe chuck 100 can arrange a wafer to correspond to a circuit site of the test head 200 by a probe chuck driving unit (not shown) while testing.

The test head 200 includes a probe card 202 including a plurality of needle units 201 arranged to contact a contact pad of one of the semiconductor DUTs on the wafer W, a pin board 204 mounted on the probe card 202 for inputting and outputting signals to a selected needle unit 201 by the relay of a switching metric circuit 203, and a plurality of source monitor units 205 connected to the pin board 204 for generating and detecting signals.

The probe card 202, the pin board 204, and the source monitor units 205 of the test head 200 can provide multiple circuit sites, for example, 36 independent circuit sites, in order to simultaneously test the plurality of semiconductor DUTs. Also, the test head 200 can provide a single circuit site formed by combining at least two circuit sites to share test resources.

A circuit site denotes a predetermined set of test resources for testing each of the semiconductor DUTs. A test resource may denote the number of contact pads of a semiconductor DUT, which is generally referred to as channels. The semiconductor DUTs arranged at the circuit site may include different test modules, each of which includes one type of predetermined test item, such as transistors, capacitors, and resistors. The different test modules may form one test module group, respectively or collectively. One test module group may be allocated to each die formed on the wafer W. Therefore, the circuit sites can be allocated to different test module groups according to an embodiment of the present invention, and the circuit sites can also be allocated to different test modules in one test module group according to another embodiment of the present invention.

The test controller 300 may be a computer such as a work station or a personal computer (PC), which can run a program for controlling the testing system. The circuit sites may be connected to the test controller 300 through a system bus. The test controller 300 may provide an operator interface in order to create a test map.

As described above, the circuit sites of the parallel type semiconductor IC testing system according to the embodiments of the present invention can independently perform different tests in order to test different test items or at least two circuit sites may be combined to function as one circuit site. The control program of the test controller 300 can address and control the circuit sites through the system bus in order to independently use test resources allocated to the circuit sites or in order to collectively use test resources allocated to the circuit sites by combining them into a single circuit site. Also, the test controller 300 can load an individual test program to each of the circuit sites. Therefore, the parallel type semiconductor IC testing system according to the embodiments of the present invention can effectively use test resources because it is possible to expand and concentrate the test resources of a parallel type semiconductor IC testing system.

Hereinafter, circuit sites according to various embodiments of the present invention will be described in detail.

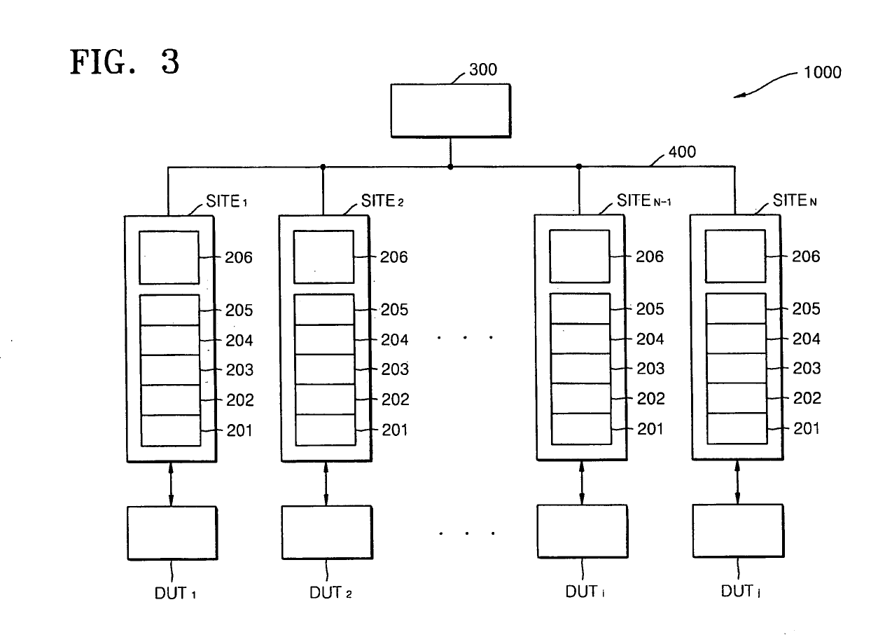

FIG. 3 is a block diagram schematically illustrating circuit sites SITE1, SITE2, . . . , SITE N−1, and SITE N of a parallel type semiconductor IC testing system 1000 according to an embodiment of the present invention.

Referring to FIG. 3, each of the circuit sites SITE1, SITE2, . . . , SITE N−1, and SITE N may be allocated with a needle unit 201, a switching metric circuit 203, a pin board 204, and a source monitor unit 205 similar to those illustrated in FIG. 2. For example, N may be 36. In order to enable each of the circuit sites SITE1, SITE2, . . . , SITE N−1, and SITE N to independently perform a test, each of the test heads 200 may further include a micro processor 206, which is allocated to each of the circuit sites independently.

In order to simultaneously test different types of semiconductor devices DUT1, DUT2, . . . , DUTi, and DUTj, each of the circuit sites SITE1, SITE2, . . . , SITE N−1, and SITE N can be loaded with different types of test programs which can be run independently. For example, the semiconductor devices DUT1, DUT2, . . . , DUTi, and DUTj may be different types of test items such as a transistor, a capacitor, a resistor, and an inductor. In order to simultaneously test the semiconductor devices DUT1, DUT2, . . . , DUTi, and DUTj, different test programs may be loaded at the circuit sites SITE1, SITE2, . . . , SITE N−1, and SITE N and may run independently. Accordingly, test resources allocated to each of the circuit sites SITE1, SITE2, . . . , SITE N−1, and SITE N can be independently used.

According to some embodiments of the present invention, the circuit sites SITE1, SITE2, . . . , SITE N−1, and SITE N may have different test resources in order to test the different types of semiconductor devices DUT1, DUT2, . . . , DUTi, and DUTj. For example, one circuit site SITE1 may have 36 channels, and the other circuit sites SITE2, . . . , SITE N−1, and SITE N may each have 68 channels.

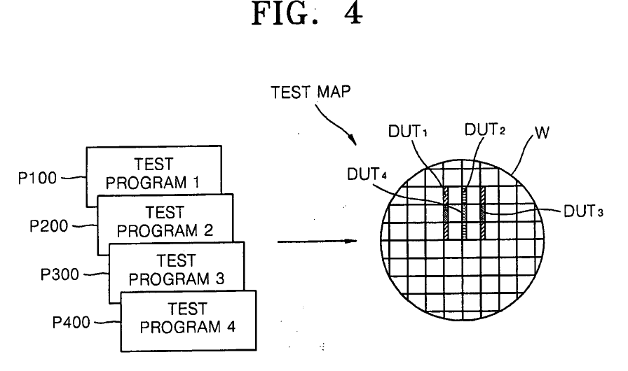

FIG. 4 is a diagram illustrating a test map for an exemplary test mode performed by the parallel type semiconductor IC testing system 1000 illustrated in FIG. 3, according to an embodiment of the present invention.

Referring to FIG. 4, a semiconductor substrate W such as a wafer including different types of semiconductor devices is loaded on a probe chuck of a parallel type semiconductor IC testing system, and an operator selects test items. Then, in order to test the selected test items, different types of semiconductor devices DUT1, DUT2, DUT3, and DUT4 arranged at different test locations are selected. Accordingly, a test map may be created, which is defined by the test items and the test locations of the semiconductor devices on a wafer. The test controller 300 of the parallel type semiconductor IC testing system 1000 may provide an operator interface to create such a test map.

For example, the semiconductor device DUT1 may be a transistor, the semiconductor device DUT2 may be a diode, the semiconductor device DUT3 may be a dielectric device, and the semiconductor device DUT4 may be a resistor. The semiconductor devices DUT1, DUT2, DUT3, and DUT4 may be dummy semiconductor devices for test, and may be formed on a scribe line between dies of a wafer.

The parallel type semiconductor IC testing system 100 arranges the semiconductor devices DUT1, DUT2, DUT3, and DUT4 formed on the semiconductor substrate W at circuit sites of the test head 200 using a probe chuck based on the defined test map. Then, the different types of the semiconductor devices DUT1, DUT2, DUT3, and DUT4 are simultaneously and independently tested by test programs P100, P200, P300, and P400, loaded on each of the circuit sites, thereby testing all of determined test items in test locations. As described above, the test result data for the different types of test items can be obtained through a single test according to the present embodiment. Therefore, the overall testing time can be shortened, and the testing throughput can be increased.

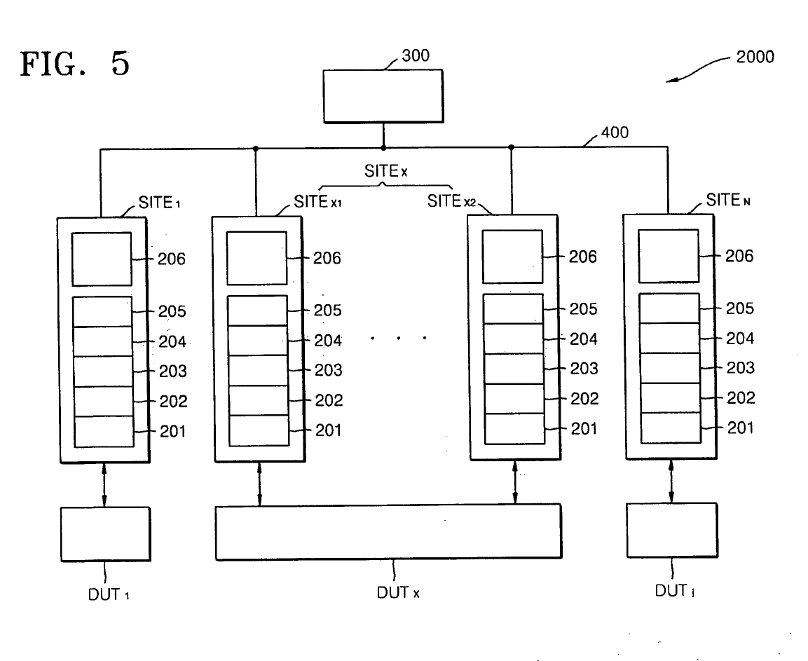

FIG. 5 is a block diagram schematically illustrating circuit sites SITE1, SITE X, and SITE N of a parallel type semiconductor IC testing system 2000 according to another embodiment of the present invention.

Referring to FIG. 5, the parallel type semiconductor IC testing system 2000 may form one large equivalent circuit site SITE x by combining at least two circuit sites SITEx1, and SITEx2. For example, more than 100 contact pads may be required in order to test a flash memory device, which means that the test resource of the circuit site needs more than 100 channels. If each of the circuit sites SITE1, SITEx1, SITEx2, and SITE N has 64 channels, one circuit site SITEx having 128 channels can be provided by combining two sites SITEx1 and SITEx2 as a single circuit site. That is, a large semiconductor device DUTx such as a flash memory device requiring more than 100 channels can be tested according to the present embodiment.

As described above, the parallel type semiconductor IC testing system 2000 according to the present embodiment can provide one large circuit site having expanded resources by combining the resources of existing equipment. The parallel type semiconductor IC testing system 2000 can be effectively used under the current situation that semiconductor devices have become more complicated and their parameters have become more diversified. Also, the circuit sites SITE1, SITEx, and SITE N can also be loaded with different types of test programs which can be run independently and simultaneously in order to test different types of semiconductor devices DUT1, DUTx, and DUTj at the same time. Accordingly, the test resources allocated to each of the circuit sites can be independently used.

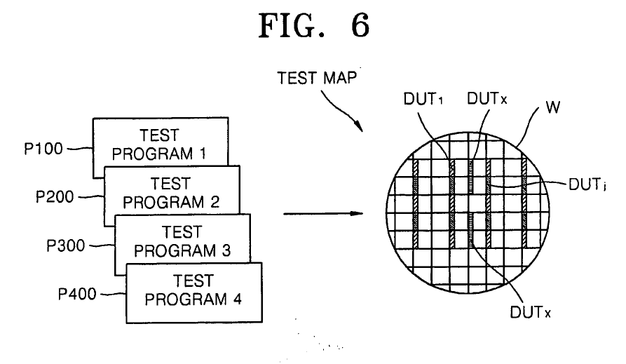

FIG. 6 is a diagram illustrating a test map for an exemplary test mode performed by the parallel type semiconductor IC testing system 2000 illustrated in FIG. 5, according to an embodiment of the present invention.

Referring to FIG. 6, an operator selects test items. Then, the operator selects different types of semiconductor devices DUT1, DUTx, and DUT4 arranged at different test locations on a wafer W in order to test the selected test items. Accordingly, a test map which may be determined by the test items and the DUT locations on the wafer W may be created, as shown. The semiconductor device DUT1 may be a transistor, the semiconductor device DUTx may be a flash memory device requiring expanded test resources, and the semiconductor device DUT3 may be a resistor.

In the parallel type semiconductor IC testing system 2000, the semiconductor device DUT1 can be tested by the circuit site SITE1 illustrated in FIG. 5, the semiconductor device DUTx can be tested by the circuit site SITEx provided by combining the circuit sites SITEx1 and SITEx2, and the semiconductor device DUTj can be tested by the circuit site SITEN according to embodiments the present embodiment. The semiconductor devices DUT1, DUTx, and DUT4 can be tested sequentially, or can be tested simultaneously by loading test programs P100, P200, P300, and P400 at the circuit sites SITE1, SITEx, and SITEj independently, as described above.

As described above, the parallel type semiconductor IC testing system according to the present invention includes a plurality of circuit sites for testing different types of semiconductor devices DUT simultaneously and independently. That is, different types of test items can be tested at the same time. Therefore, the overall testing time can be shortened and the test throughput can be increased.

The parallel type semiconductor IC testing system according to the present invention includes two or more circuit sites that can be used as a single circuit site by combining allocated resources. Since the semiconductor devices are tested using redundant test resources, the resources of such an expensive test system are optimally utilized not to remain idle.

In the parallel type semiconductor IC testing method according to the present invention, different types of semiconductor devices DUT can be tested independently and simultaneously. That is, by testing different types of test items in parallel, the overall testing time can be reduced and the test throughput can be increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A system for testing semiconductor devices in parallel, comprising:
a probe chuck for loading a plurality of different types of semiconductor DUTs (device under test);
a test head for providing a plurality of circuit sites to independently and simultaneously test the different types of semiconductor DUTs; and
a test controller for controlling the test head and the probe chuck.

2. The system of claim 1, wherein the test head comprises:
a probe card having a needle unit arranged to contact contact pads of the semiconductor DUTs;
a pin board mounted on the probe card for inputting and outputting signals to the needle unit selected by a relay of a switching metric circuit; and
a plurality of source monitor units connected to the pin board for generating and detecting the signals.

3. The system of claim 1, wherein each of the circuit sites comprises a microprocessor.

4. The system of claim 1, wherein different types of test programs are allocated to the circuit sites and run independently.

5. The system of claim 1, wherein, different resources are provided to each of the circuit sites.

6. The system of claim 1, wherein the test controller provides an operator interface for creating a test map.

7. The system of claim 1, wherein each of the semiconductor DUTs is selected from the group consisting of a transistor, a capacitor, and a resistor.

8. The system of claim 1, wherein the semiconductor DUTs are formed on a scribe line disposed between dies on a wafer.

9. A system for testing semiconductor devices in parallel, comprising:
a probe chuck loadable with different types of semiconductor DUTs;
a test head for providing at least two circuit sites that can be used as a single circuit site by combining allocated resources; and
a test controller for controlling the test head and the probe chuck.

10. The system of claim 9, wherein the test head comprises:
a probe card having a needle unit arranged to contact contact pads of the semiconductor DUTs;
a pin board mounted on the probe card for inputting and outputting signals to the needle unit selected by a relay of a switching metric circuit; and
a plurality of source monitor units connected to the pin board for generating and detecting the signals.

11. The system of claim 9, wherein each of the circuit sites comprises a microprocessor.

12. The system of claim 9, wherein different types of test programs are allocated to the circuit sites and run independently

13. The system of claim 9, wherein the test controller provides an operator interface for creating a test map.

14. The system of claim 9, wherein the semiconductor DUTs comprise a flash memory device.

15. The system of claim 9, wherein the semiconductor DUTs are formed on a scribe line disposed between dies on a wafer.

16. A method of testing semiconductor devices in parallel, comprising:
providing a plurality of different types of semiconductor DUTs;
selecting at least two different types of test items;
selecting the different types of semiconductor DUTs arranged at different locations in order to test the test items; and
testing the different types of semiconductor DUTs independently and simultaneously.

17. The method of claim 16, wherein the semiconductor DUTs are test devices formed at a scribe line arranged between dies of a semiconductor substrate.

18. The method of claim 16, wherein, in the testing of the different types of semiconductor DUTs, test resources allocated to the different types of semiconductor DUTs are independently used.

19. The method of claim 16, further comprising combining test resources allocated to the semiconductor DUTs, allocating and using the combined test resources for a large semiconductor DUT when the different types of semiconductor DUTs comprise the large semiconductor DUT requiring expanded test resources.
